(19) United States
(12) Patent Application Publication
(10) Pub. No.: US 2011/0030999 A1
(43) Pub. Date: Feb. 10, 2011

(54) METAL CIRCUIT WIRING HAVING ORGANIC RESIN FOR ADHESIVE LAYERS AND METHOD OF MANUFACTURING THE SAME

(75) Inventors: Young-Il LEE, Hwasung-si (KR); Sung-Eun Kim, Suwon-si (KR); Tae-Hoon Kim, Anyang-si (KR); Young-Kwan Seo, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/634,145

(22) Filed: Dec. 9, 2009

(30) Foreign Application Priority Data
Aug. 4, 2009 (KR) 10-2009-0071789

(51) Int. Cl. H05K 1/03; H05K 3/10

(52) U.S. Cl. 174/255; 29/850; 977/773; 174/259

(57) ABSTRACT

The invention is to provide a metal circuit wiring having an organic adhesive layer, the metal circuit wirings comprising: an organic adhesive layer formed with a resin selected from the group consisting of acrylic resin, chloroprene rubber and silicone rubber resin; and metal wiring patterns formed with an ink composition including metal nanoparticles, in which the metal wiring exhibits excellent adhesive between metal nano materials and the substrate and electrical property.

### CROSS-REFERENCE TO RELATED APPLICATIONS

This application claims the benefit of Korean Patent Application No. 10-2009-0071789 filed on Aug. 4, 2009, with the Korea Intellectual Property Office, the contents of which are incorporated here by reference in their entirety.

### BACKGROUND

1. Technical Field

It relates to a metal circuit wiring composed of ink composition including organic adhesive layers formed with a resin chosen from acrylic resin, chloroprene rubber and silicone rubber resin and metal nanoparticles on a substrate and a method for manufacturing the same.

2. Description of the Related Art

There have been extensive studies in printing or forming circuit patterns on a substrate by using conductive ink in the field of printed electronics. It is necessary to form circuit wirings with reliability to commercialize the technology of printed electronics. For this purpose, it is required first and foremost to provide excellent adhesive between metal circuit patterns having conductivity and a substrate. A general conductive ink in the field of printed electronics is prepared by dispersing metal nanoparticles in an appropriate solvent. However, when such a metal nano material is cured on a substrate, the adhesive to the substrate becomes deteriorated and causes problems to form wirings having reliability afterwards. Therefore, the invention is to provide metal wirings having excellent adhesive toward a substrate and electrical conductivity and its manufacturing method.

There have been much efforts to improve the adhesive between circuit patterns and a substrate in order to form circuit wirings having reliability.

One method of such efforts is to increase the roughness of the surface of a substrate to increase an effective contact area between metal circuit patterns and the substrate or to provide an additional anchoring effect. However, when the roughness of the surface of a substrate is increased, circuit patterns to be printed become non-uniform and effective adhesive is not expected. Another method is to introduce chemical functional groups on the surface of a substrate to improve adhesive to circuit patterns. However, in this case, a chemical treatment has to be changed according to types of metal composing a substrate and circuit patterns. Another method is to form an organic adhesive layer on the surface of a substrate and then print metal wirings. In this case, it provides excellent adhesive between the substrate and metal wirings but when the organic adhesive layer has significant thermal shrinkage, the printed circuit patterns are cracked or deformed during the curing process. In addition, adhesive reinforced films having high glass transition temperature (Tg) and particular surface morphology have been also used. However, when such films are used, it is adhered all over the surface of a substrate, causing increase of the thickness of the substrate and increase of manufacturing cost for using costly film. Further, it causes tilting due to the difference of thermal expansion coefficients of the substrate and the adhesive-reinforced film.

### SUMMARY

In order to resolve such problems associated with the conventional methods, it provides metal circuit wiring and its manufacturing method, in which the metal circuit wiring is formed by employing an organic adhesive layer having excellent heat resistance, chemical resistance and affinity to metals, has minimized forming cracks and deformation, and provides excellent adhesive and electrical conductivity on a substrate.

An aspect of the invention is to provide a metal circuit wiring having an organic adhesive layer, the metal circuit wirings including: an organic adhesive layer formed with a resin selected from the group consisting of acrylic resin, chloroprene rubber and silicone rubber resin; and metal wiring patterns formed with an ink composition including metal nanoparticles.

According to an embodiment of the invention, the substrate is chosen from polyimide, polyester, epoxy, BT (Bismalemide-Triazine), PP (polypropylene) and PVC (polyvinyl chloride).

According to an embodiment, the organic adhesive layer may have a thickness of 0.1-100 μm.

Further, the metal nanoparticles may be at least one chosen from gold, silver, copper, platinum, lead, indium, palladium, rhodium, ruthenium, iridium, osmium, tungsten, nickel, tantalum, bismuth, tin, zinc, titanium, aluminum, cobalt, iron and an alloy thereof.

Another aspect of the invention is to provide a method for manufacturing a metal circuit wiring having an organic adhesive layer including: forming an organic adhesive layer of a resin chosen from acryl, chloroprene rubber and silicone rubber resin on a substrate; forming metal wiring patterns with an ink composition including metal nanoparticles on the organic adhesive layer-formed substrate; and curing the metal wiring patterns.

According to an embodiment of the invention, forming the organic adhesive layer may be performed by a method chosen from screen printing, doctor blade, spin coating, spray coating and dip coating.

Further, forming the organic adhesive layer may be carried by a heat treatment at the range of from room temperature to 200° C., in which the room temperature is about 24° C. or more.

According to an embodiment, the metal wiring patterns may be formed by a method chosen from screen method, ink jet printing method, gravure method, spray coating method and offset printing method.

### DETAILED DESCRIPTION

The invention will be described in more detail hereinafter.

According to an aspect, there is provided a metal circuit wiring having an organic adhesive layer, the metal circuit wirings comprising: an organic adhesive layer formed with a resin selected from the group consisting of acrylic resin, chloroprene rubber and silicone rubber resin; and metal wiring patterns formed with an ink composition including metal nanoparticles.

Here, the substrate may be a general printing circuit substrate which is an organic material substrate such as polyimide, polyester, epoxy, BT (Bismalemide-Triazine), PP (Poly Propylene), PVC (polyvinyl chloride) and the like.

Since such acrylic resin, chloroprene resin and silicone rubber resin have excellent adhesive to a polar material such as metal, it allows good adhesive when metal circuit wiring is formed on the adhesive layer. In addition, it may prevent the formation of cracks or deformation during the curing process which further allows excellent electrical property to the metal wring since they have excellent heat resistance, flame resistance, and chemical resistance.

The organic adhesive layer may be controlled to have a thickness of 0.1-100 μm according to shapes or thicknesses of metal wirings. When the thickness is thinner than 0.1 μm, it may be not expected to have enough adhesive and when it is more than 100 μm, it may deteriorate electrical conductivity of metal wirings.

According to an embodiment of the invention, the metal nanoparticles may be chosen from gold, silver, copper, platinum, lead, indium, palladium, rhodium, ruthenium, iridium, osmium, tungsten, nickel, tantalum, bismuth, tin, zinc, titanium, aluminum, cobalt, iron and an alloy thereof.

According to another aspect, there is provided a method for manufacturing a metal circuit wiring having an organic adhesive layer including: forming the organic adhesive layer of a resin chosen from acryl, chloroprene rubber and silicone rubber resin on a substrate; forming metal wiring patterns with an ink composition including metal nanoparticles on the organic adhesive layer-formed substrate; and curing the metal wiring patterns.

According to an embodiment, forming the organic adhesive layer may be any method with no limitation, if it provides a uniform adhesive layer on the substrate, preferably one chosen from screen printing, doctor blade, spin coating, spray coating and dip coating.

Preferably, the organic adhesive layer may be formed by a heat treatment at the range of from room temperature to 200° C.

According to an embodiment, the metal wiring may be formed by a screen method, an ink-jet printing method, a gravure method, a spray coating method or an offset printing method but it is not limited thereto.

Hereinafter, although more detailed descriptions will be given by examples, those are only for explanation and there is no intention to limit the invention.

The heat treatment applied in the following Examples is performed at 100° C. for 10 mins. However, since such temperature may be changed according to kinds of resin, it may be controlled in the range of from room temperature to 200° C. Degree of curing may vary with the temperature of heat treatment and affect adhesiveness.

### Example

### Preparation of Metal Wiring Haying Acrylic Resin, Chloroprene, or Silicon Rubber Adhesive Layer

40 wt % concentration of Cu nano ink, in which Cu nanoparticles having an average particle size of 7 nm were uniformly dispersed, was prepared. And 40 wt % concentration of Ag nano ink, in which Ag nanoparticles having an average particle size of 7 nm were uniformly dispersed, was prepared.

An adhesive layer was formed on a polyimide substrate with FA700(acrylic resin, purchased from Okong Adhesives) by a spin coating method to have a thickness of 1-5 μm. It was then cured by a heat treatment.

Each adhesive layer was also formed with 805SD (chloroprene rubber, purchased from Dongbu Fine Chemicals) and ME151(silicon rubber, purchased from Momentive Performance Materials Inc.), respectively.

Print wirings were then formed to be a length of 1 cm and a width of 200 μm an by using the metal nano ink and ink-jet head. Ag wiring was heat-treated at 250° C. for 1 hr under air atmosphere and Cu wiring was at 200° C. for 1 hr under reduction atmospheres.

A metal wiring having acrylic resin (FA700), chloroprene rubber (805SD), silicon rubber (ME151), respectively was formed.

### Comparison Example

### Comparison on Electrical Property According to Types of Organic Adhesive Layer

Ag and Cu print wirings with no organic adhesive layer or with a different resin were prepared by the same procedure in Example.

Resins used to form an organic adhesive layer were BL-1 (polyvinylbutyral, purchased from Sekisui Chemical Co.), HTL (polyester resin, purchased from Evonik Degussa Corp.), Macromelt (polyamid resin, purchased from Henkel), YD-128o (epoxy resin, purchased from Kukdo Chemicals Co.), respectively for Comparison Examples.

Adhesiveness and electrical properties of the wirings prepared in Examples and Comparison Examples were determined by performing adhesive test and measuring specific resistance.

The adhesive test was performed by using 3M tape having adhesiveness of 0.65 kN/m and BYK gardener according to ASTM D3359(Measuring Adhesion by Tape Test). The adhesion was rated as follows.

<Adhesive Rating>
5B: No noticeable removal of the coating
4B: Less than 5% of the coating removed
3B: 5-15% of the coating removed
2B: 15-35% of the coating removed
1B: 35-65% of the coating removed
0B: more than 65% of the coating removed which is worse than 1B

TABLE 1

| | metal | adhesive | Adhesive | Specific resistance |
|---|---|---|---|---|
| | nano ink | layer | rating | (μΩcm) |
| Control 1 | Cu | — | 0B | 5.2 |
| Control 2 | Ag | — | 0B | 4.5 |
| Comparison | Cu | BL-1 | 4B | 60 |
| Example 1 | | | | |
| Comparison | Cu | LTH | 2B | 10 |
| Example 2 | | | | |
| Comparison | Cu | Macromelt | 5B | 21 |
| Example 3 | | 6900 | | |
| Comparison | Cu | YD128 | 1B | 8.5 |
| Example 4 | | | | |
| Example 1 | Cu | 805SD | 5B | 8.7 |
| Example 2 | Cu | ME151 | 4B | 9.5 |
| Example 3 | Cu | FA700 | 5B | 6.3 |
| Example 4 | Ag | 805SD | 5B | 8.7 |
| Example 5 | Ag | ME151 | 5B | 8.5 |
| Example 6 | Ag | FA700 | 5B | 5.8 |

When an organic adhesive layer is used on a substrate, it usually deteriorates the electrical property. Thus, the electrical property shows the best in case of Control 1 and Control 2 which have no organic adhesive layer. However, in this case, it shows excellent electrical property but has no adhesiveness so that it may not be suitable for forming metal wirings. Therefore, even though an organic adhesive layer is used, it is important to provide comparative electrical property to that with no organic adhesive layer.

BL-1 (polyvinylbutyral, purchased from Sekisui Chemical Co.), HTL (polyester resin, purchased from Evonik Degussa Corp.), Macromelt (polyamid resin, purchased from Henkel), YD-128 (epoxy resin, purchased from Kukdo Chemicals Co.) were used as an organic adhesive layer in Comparison Examples. There is no one showing both excellent electrical property and excellent adhesive. Even though some show good adhesiveness, they have high specific resistance for wiring cracks caused by penetration or flow of adhesives between wirings. On the other hand, even though some show excellent specific resistance and less cracks, they have poor adhesiveness.

However, as shown in Table 1, the metal wiring having an organic adhesive layer prepared in Examples 1 to 6 show better electrical property and adhesiveness than those in Control and Comparison Examples.

While it has been described with reference to particular embodiments, it is to be appreciated that various changes and modifications may be made by those skilled in the art without departing from the spirit and scope of the embodiment herein, as defined by the appended claims and their equivalents.

What is claimed is:

1. A metal circuit wiring having an organic adhesive layer, the metal circuit wirings comprising:
an organic adhesive layer formed with a resin selected from the group consisting of acrylic resin, chloroprene rubber and silicone rubber resin; and metal nanoparticles; and
metal wiring patterns formed with an ink composition including metal nanoparticles.

2. The metal circuit wiring having an organic adhesive layer of claim 1, wherein the substrate is selected from the group consisting of polyimide, polyester, epoxy, BT (Bismalemide-Triazine), PP (polypropylene) and PVC (polyvinyl chloride).

3. The metal circuit wiring having an organic adhesive layer of claim 1, wherein the organic adhesive layer has a thickness of 0.1-100 μm.

4. The metal circuit wiring having an organic adhesive layer of claim 1, wherein the metal nanoparticles is at least one selected from the group consisting of gold, silver, copper, platinum, lead, indium, palladium, rhodium, ruthenium, iridium, osmium, tungsten, nickel, tantalum, bismuth, tin, zinc, titanium, aluminum, cobalt, iron and an alloy thereof.

5. A method for manufacturing a metal circuit wiring having an organic adhesive layer, the method comprising:
forming an organic adhesive layer of a resin selected from the group consisting of acryl, chloroprene rubber and silicone rubber resin on a substrate;
forming metal wiring patterns with an ink composition comprising metal nanoparticles on the organic adhesive layer-formed substrate; and
curing the metal wiring patterns.

6. The method of claim 5, wherein the substrate is selected from the group consisting of polyimide, polyester, epoxy, BT (Bismalemide-Triazine), PP (Poly Propylene) and PVC (polyvinyl chloride).

7. The method of claim 5, wherein the organic adhesive layer has a thickness of 0.1-100 μm.

8. The method of claim 5, wherein the metal nanoparticles is at least one selected from the group consisting of gold, silver, copper, platinum, lead, indium, palladium, rhodium, ruthenium, iridium, osmium, tungsten, nickel, tantalum, bismuth, tin, zinc, titanium, aluminum, cobalt, iron and an alloy thereof.

9. The method of claim 5, wherein the organic adhesive layer is formed by a method selected from the group consisting of screen printing, doctor blade, spin coating, spray coating and dip coating.

10. The method of claim 5, wherein the organic adhesive layer is heat-treated at the range of from 24° C. to 200° C.

11. The method of claim 5, wherein the metal wiring patterns are formed by a method selected from the group consisting of screen method, ink jet printing method, gravure method, spray coating method and offset printing method.
